(19) United States
(12) Patent Application Publication
(10) Pub. No.: US 2015/0044831 A1
(43) Pub. Date: Feb. 12, 2015

(54) SEMICONDUCTOR PROCESS

(71) Applicant: UNITED MICROELECTRONICS CORP., Hsin-Chu City (TW)

(72) Inventors: Yu-Cheng Tung, Kaohsiung City (TW); Chin-I Liao, Tainan City (TW)

(73) Assignee: UNITED MICROELECTRONICS CORP., Hsin-Chu City (TW)

(21) Appl. No.: 13/962,959

(22) Filed: Aug. 9, 2013

(51) Int. Cl. H01L 21/8238

(52) U.S. Cl. CPC H01L 21/823864
USPC 438/230

(57) ABSTRACT

A semiconductor process includes the following steps. A first gate and a second gate are formed on a substrate. A first stress layer is formed to cover the first gate and the second gate. The first stress layer covering the first gate is etched to form a first spacer beside the first gate, but reserves the first stress layer covering the second gate. A first epitaxial layer is formed beside the first spacer. The first stress layer and the first spacer are entirely removed. A second stress layer is formed to cover the first gate and the second gate. The second stress layer covering the second gate is etched to form a second spacer beside the second gate, but reserves the second stress layer covering the first gate. A second epitaxial layer is formed beside the second spacer. The second stress layer and the second spacer are entirely removed.

### BACKGROUND OF THE INVENTION

1. Field of the Invention

The present invention relates generally to a semiconductor process, and more specifically to a semiconductor process that applies various crystal strain technologies into CMOS transistors.

2. Description of the Prior Art

For decades, chip manufacturers have made complementary metal-oxide-semiconductor (CMOS) transistors faster by making them smaller. As the semiconductor processes advance to very deep sub micron era, such as 65-nm node or beyond, how to increase the driving current in MOS transistors has become a critical issue. In order to improve the device performances, strain technology has been developed. Strain technology is becoming more and more attractive as a means for getting better performances in the field of MOS transistor fabrication. Putting a strain on a semiconductor crystal alters the speed at which charges move through that crystal. Strain makes CMOS transistors work better by enabling electrical charges, such as electrons, to pass more easily through the silicon lattice of the gate channel.

Generally, strain in silicon can be induced in different ways: through stresses created by films in a form of poly stressors or contact etch stop layers (CESL) and structures that surround the transistor, called process-induced strain; or by employing a strained silicon wafer, where the top layer of silicon is typically grown on top of a crystalline lattice that is larger/smaller than that of silicon.

Specifically, desired stresses induced into an NMOS transistor and a PMOS transistor are opposite, therefore materials and processes for the stress layers are different. Thus, it becomes an important issue about integrating crystal strain technologies into a CMOS transistor having an NMOS transistor and a PMOS transistor.

### SUMMARY OF THE INVENTION

The present invention provides a semiconductor process, which integrates various crystal strain technologies into a CMOS transistor.

The present invention provides a semiconductor process including the following steps. A first gate and a second gate are formed on a substrate. A first stress layer is formed to cover the first gate and the second gate. The first stress layer covering the first gate is etched to form a first spacer on the substrate beside the first gate, but reserves the first stress layer covering the second gate. A first epitaxial layer is formed in the substrate beside the first spacer. The first stress layer and the first spacer are removed completely. A second stress layer is formed to cover the first gate and the second gate. The second stress layer covering the second gate is etched to form a second spacer on the substrate beside the second gate, but reserves the second stress layer covering the first gate. A second epitaxial layer is formed in the substrate beside the second spacer. The second stress layer and the second spacer are removed completely.

According to the above, the present invention provides a semiconductor process, which forms a first stress layer, a first spacer from the first stress layer, and then a first epitaxial layer by the first spacer; forms a second stress layer, forms a second spacer from the second stress layer, and then forms a second epitaxial layer by the second spacer. In this way, various crystal strain technologies can be integrated into semiconductor structures, and processes can be simplified. Moreover, compressive stresses can be induced in a gate channel for forming a PMOS transistor by the first stress layer and the first epitaxial layer, and tensile stresses can be induced in another gate channel for forming an NMOS transistor by the second stress layer and the second epitaxial layer through selecting the materials of the first stress layer, the first epitaxial layer, the second stress layer and the second epitaxial layer, therefore various crystal strain technologies can be integrated into a CMOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 schematically depict cross-sectional views of a semiconductor process according to an embodiment of the present invention.

### DETAILED DESCRIPTION

An embodiment described as follows depicts processes of integrating silicon strain technologies into a CMOS transistor. In this embodiment, a tri-gate MOSFET is formed, but it is not limited thereto. In another embodiment, the present invention can also be applied to other non-planar transistors such as a multi-gate MOSFET or planar transistors, depending upon the needs.

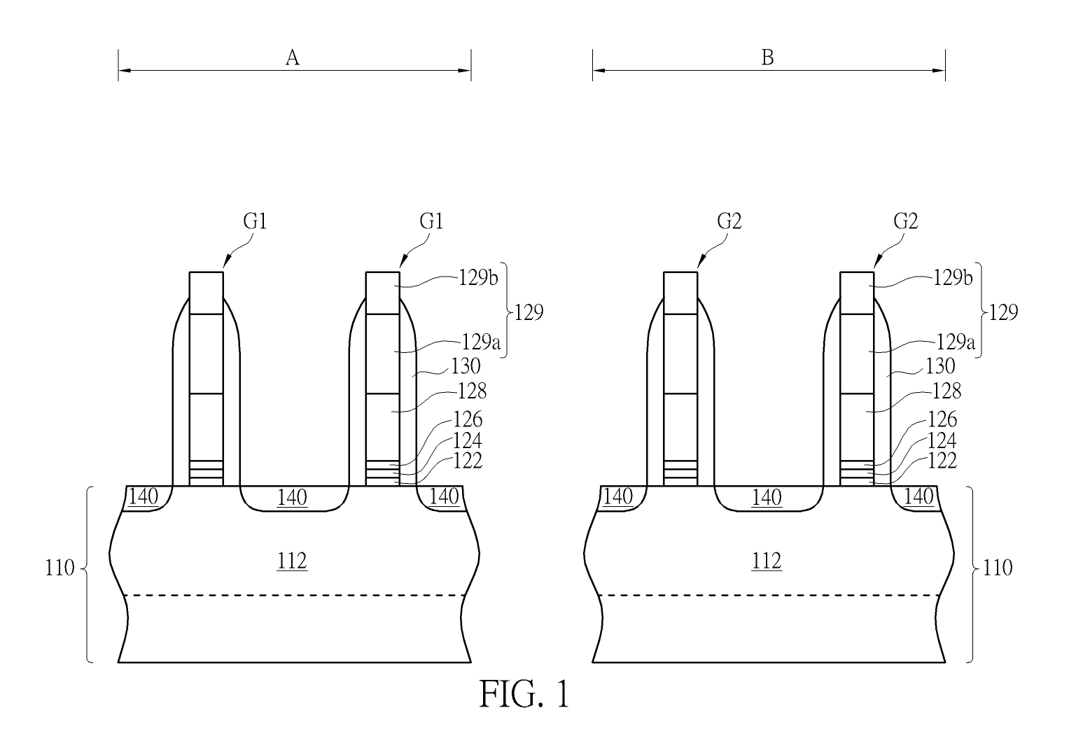

FIGS. 1-11 schematically depict cross-sectional views of a semiconductor process according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate.

The substrate 110 has a fin-shaped structure 112. The method for forming the fin-shaped structure 112 may include the following. A bulk bottom substrate (not shown) is provided. A hard mask layer (not shown) is formed on the bulk bottom substrate (not shown) and is patterned to define the location of the fin-shaped structure 112, which will be formed in the bulk bottom substrate (not shown). An etching process is performed to form the fin-shaped structure 112 in the bulk bottom substrate (not shown). Thus, the fin-shaped structure 112 located in the substrate 110 is formed completely. In one embodiment, the hard mask layer (not shown) is removed after the fin-shaped structure 112 is formed, and a tri-gate MOSFET can be formed in the following processes. There are three contact faces between the fin structure 112 and the following formed dielectric layer functioning as a carrier channel whose width is wider than a channel width in a conventional planar MOSFET. When a driving voltage is applied, the tri-gate MOSFET produces an on-current twice higher compared to the conventional planar MOSFET. In another embodiment, the hard mask layer (not shown) is reserved to form a fin field effect transistor (Fin FET), which is another kind of multi-gate MOSFET. Due to the hard mask layer (not shown) being reserved in the fin field effect transistor, there are only two contact faces between the fin structure 112 and the following formed dielectric layer.

Moreover, the present invention can also be applied in other semiconductor substrates. For example, a silicon-on-insulator substrate (not shown) is provided, and then a single crystalline silicon layer being a top part of the silicon-on-insulator substrate (not shown) is etched till an oxide layer being a middle part of the silicon-on-insulator substrate (not shown) is exposed, i.e. the fin-shaped structure formed on the silicon-on-insulator substrate (not shown) is finished. Furthermore, the number of fin-shaped structures 112 is not limited. FIGS. 1-11 schematically depict cross-sectional views of a desired formed semiconductor structure of the present invention and a plurality of fin-shaped structures 112 may be arranged parallel to each other along the direction toward the surface.

Please refer to FIG. 1; a substrate 110 has a first area A and a second area B. In this embodiment, the first area A is for forming PMOS transistors therein while the second area B is for forming NMOS transistors therein, but it is not limited thereto. In another embodiment, the first area A is for forming NMOS transistors therein while the second area B is for forming PMOS transistors therein. Since transistors with different electrical types are formed in the first area A and the second area B, different processes or materials of stress layers are needed to induce compressive stresses and tensile stresses in gate channels while using silicon strain technologies. Moreover, the first area A and the second area B may have transistors with common electrical type formed therein. For example, only PMOS transistors or only NMOS transistors are formed in the first area A and the second area B. Therefore, stresses induced in gate channels in the first area A and the second area B can be enhanced or forced with strength of different degrees by forming stress layers many times. Moreover, an isolation structure (not shown) may be formed in the substrate 110 between the first area A and the second area B to electrically isolate each transistor. The isolation structure may be a shallow trench isolation (STI) structure, which may be formed by a shallow trench isolation process, and the forming method is known in the art.

A buffer layer (not shown), a gate dielectric layer (not shown), a barrier layer (not shown), a sacrificial electrode layer (not shown) and a cap layer (not shown) are sequentially formed from bottom to top and cover the substrate 110. The cap layer (not shown), the sacrificial electrode layer (not shown), the barrier layer (not shown), the gate dielectric layer (not shown) and the buffer layer (not shown) are patterned to form a buffer layer 122, a gate dielectric layer 124, a barrier layer 126, a sacrificial electrode layer 128 and a cap layer 129 on the substrate 110. This means that two first gates G1 in the first area A and two second gates G2 in the second area B including the buffer layer 122, the gate dielectric layer 124, the barrier layer 126, the sacrificial electrode layer 126 and the cap layer 128 are formed. In this embodiment, there are two gates respectively depicted in the first area A and in the second area B for illustrating the present invention clearly. However, the number of gates is not restricted to it, and may vary upon the needs.

The buffer layer 122 may be an oxide layer, which may be formed through a chemical oxide process or a thermal oxide process, but it is not limited thereto. The buffer layer 122 is located between the gate dielectric layer 124 and the substrate 110 to buffer the gate dielectric layer 124 and the substrate 110. Since a gate-last for high-k first process is applied in this embodiment, the gate dielectric layer 124 is a gate dielectric layer having a high dielectric constant, which may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but it is not limited thereto. In another embodiment, wherein a gate-last for high-k last process is applied, the gate dielectric layer 124 is removed in later processes and then a gate dielectric layer having a high dielectric constant is formed. Therefore, the material of the gate dielectric layer 124 may be just a sacrificial material suitable for being removed in later processes. The barrier layer 126 is located on the gate dielectric layer 124 to prevent above disposed metals from diffusing downwards to the gate dielectric layer 124 and from polluting the gate dielectric layer 124. The barrier layer 126 may be a single layer structure or a multilayer structure composed of tantalum nitride (TaN) or titanium nitride (TiN). The sacrificial electrode layer 128 may be made of polysilicon, but it is not limited thereto. The cap layer 129 may be a single layer or a multilayer composed of a nitride layer or an oxide layer etc used as a patterned hard mask, but it is not limited thereto. In this embodiment, the cap layer 128 is a dual layer composed of a nitride layer 129a and an oxide layer 129b from bottom to top. Thus, the nitride layer 129a and the oxide layer 129b can be hark masks for later etching processes due to their etching selectivity, which means that they have different etching rates during an etching process.

A spacer 130 is formed on the substrate 110 beside the first gates G1 and the second gates G2 respectively. The method of forming the spacer 130 may include the following. A spacer material (not shown) is formed to entirely cover the first gates G1, the second gates G2 and the substrate 110. Then, the spacer material is etched to form the spacers 130 on the substrate 110 beside the first gates G1 and the second gates G2 respectively. The spacers 130 may have a single layer or a multilayer composed of nitride or/and oxide etc. In this embodiment, a lightly doped ion implantation process may be performed to self-align and form a lightly doped source/drain 140 in the substrate 110 beside each of the spacers 130, but it is not limited thereto. The lightly doped source/drain 140 may be formed in later formed processes. For instance, the lightly doped source/drain 140 may be formed between two later formed epitaxial layers or after all epitaxial layers are formed. Since different processing temperatures are needed to form the lightly doped source/drains 140, form epitaxial layers or form source/drains 140, different processing orders can be carried out depending upon practical needs such as the physical or chemical properties of dopants in this processes.

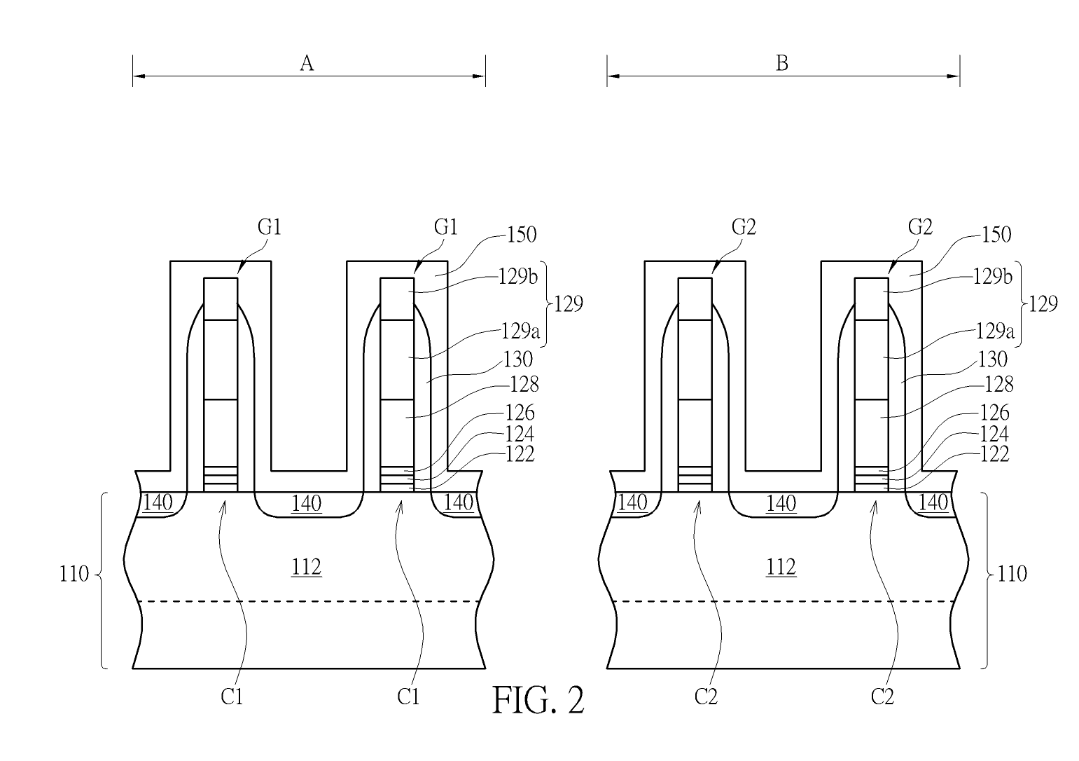

As shown in FIG. 2, a first stress layer 150 is formed to entirely cover the first gates G1 and the second gates G2. The first stress layer 150 may be a doped stress layer such as a doped nitride layer or etc, having the capability of forcing stresses in gate channels C1 below the first gates G1. In this embodiment, since the first gates G1 used for forming PMOS transistors and the second gates G2 used for forming NMOS transistors, compressive stress is needed to be induced in the gate channels C1 and tensile stress is needed to be induced in the gate channels C2 to enhance electrical holes and electrons passing through the gate channels C1 and C2, thereby improving the carrier mobility of the first gates G1 and the second gates G2. Thus, the first stress layer 150 is a compressive stress layer to induce compressive stress in the gate channels C1 for forming PMOS transistors in the first area A, but it is not limited thereto.

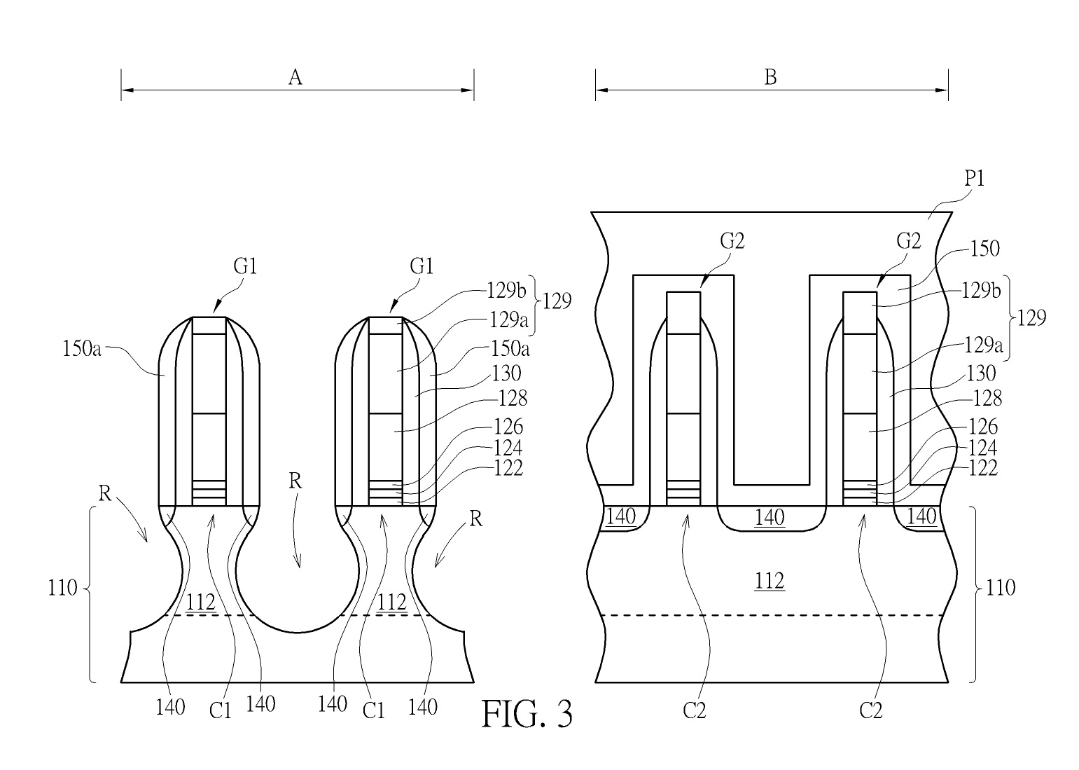

As shown in FIG. 3, the first stress layer 150 covering the first area A is etched to form a first spacer 150a having capability of inducing stresses on the substrate 110 beside each of the first gates G1, while reserving the first stress layer 150 covering the second area B. More precisely, a material P1 covers the second area B but exposes the first area A, and then the first stress layer 150 in the first area A is etched to form the first spacer 150a on the substrate 110 beside each of the first gates G1 while reserving the first stress layer 150 in the second area B. Thereafter, the material P1 in the second area B is removed. In this embodiment, the material P1 is a light sensitive material such as a photoresist, but it is not limited thereto. Furthermore, after the material P1 is covered, a partial stress strengthening process such as an ultraviolet (UV) light illuminating process may be selectively performed in the first area A to enhance stresses in the gate channels C1 induced by the first stress layer 150 or the first spacers 150a.

After the first spacers 150a are formed and before the material P1 in the second area B is removed, recesses R may be formed in the substrate 110 beside the first spacers 150a. In this embodiment, the recesses R extend to the substrate 110 below the fin-shaped structures 112. In another embodiment, the recesses R may just be formed in the fin-shaped structures 112, depending upon the needs. In this embodiment, the first spacers 150a are formed and the recesses R are formed in the same process to simplify processes. In another embodiment, the first spacers 150a and the recesses R may be formed during different processes, and the first spacers 150a and the recesses R may be formed through several processes respectively.

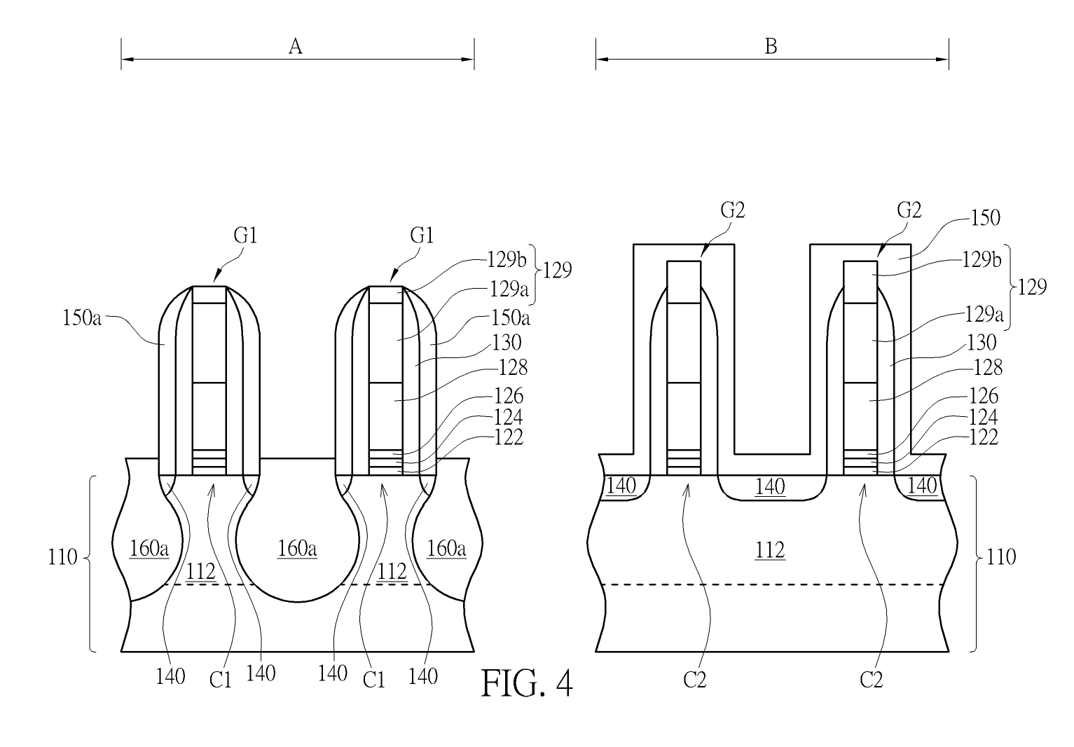

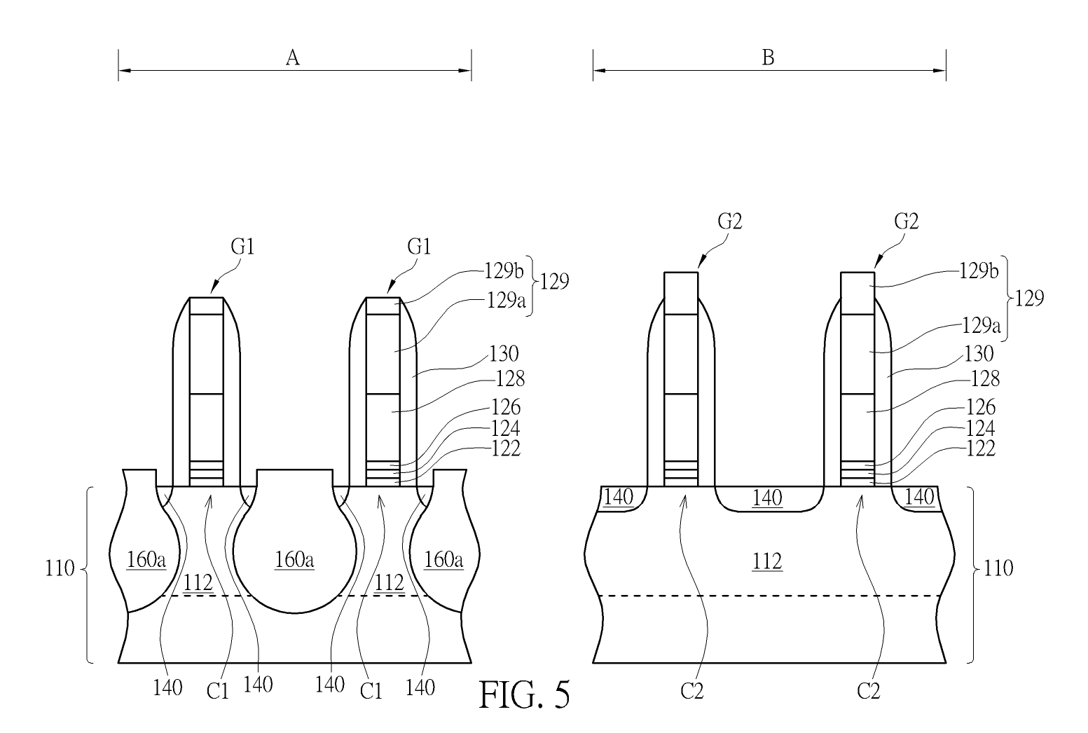

As shown in FIG. 4, a first epitaxial layer 160a is formed in each of the recesses R. In this embodiment, since the PMOS transistors are formed in the first area A, the first epitaxial layers 160a may preferably be silicon germanium epitaxial layers, but it is not limited thereto. Then, the first stress layer 150 and the first spacers 150a may be removed at the same time as shown in FIG. 5. In this embodiment, the recesses R are formed and then the first epitaxial layers 160a are formed in the recesses R. In another embodiment, the first epitaxial layers 160a may be formed in the substrate 110 beside the first spacers 150a by doping the substrate 110 directly without forming the recesses R first.

After the first epitaxial layers 160a are formed, the steps of forming the lightly doped source/drains 140 may be selectively performed at this time instead.

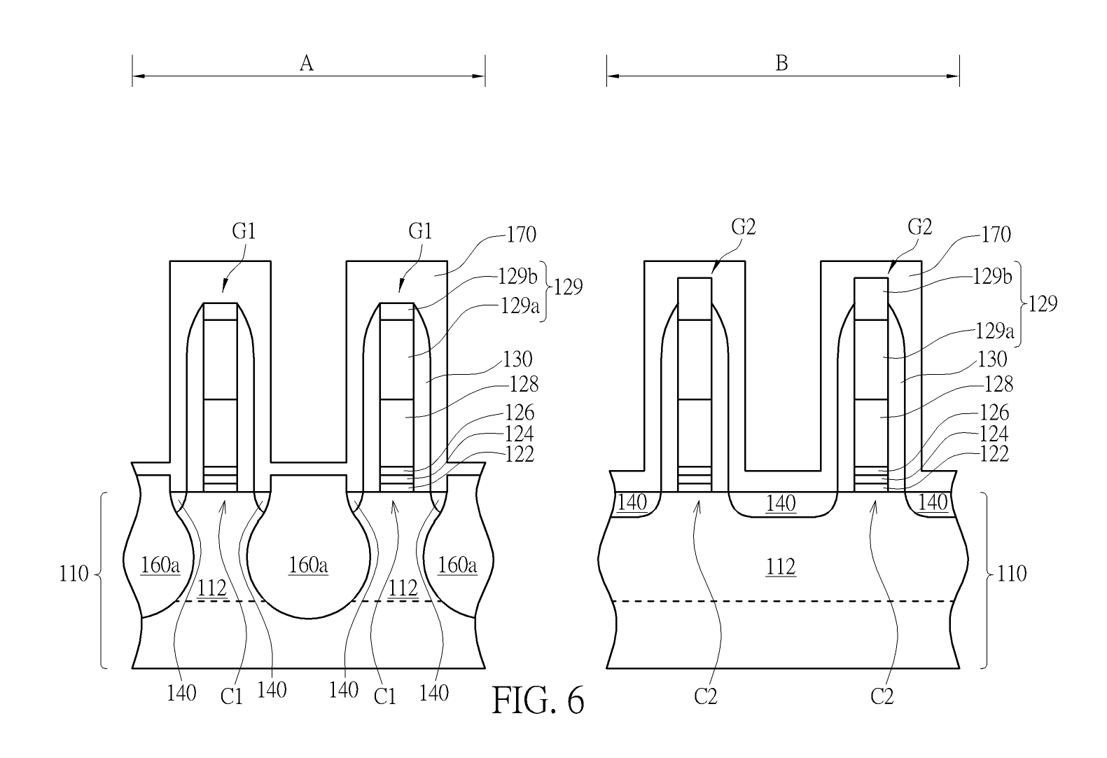

As shown in FIG. 6, a second stress layer 170 is formed to entirely cover the first gates G1 and the second gates G2. The second stress layer 170 may be a doped stress layer such as a doped nitride layer having the capability of forcing stresses in gate channels C2 below the second gates G2. In this embodiment, since the second gates G2 are used for forming NMOS transistors, tensile stress is needed to be induced in the gate channels C2 to enhance the carrier mobility of the second gates G2. Thus, the second stress layer 170 is a tensile stress layer, but it is not limited thereto.

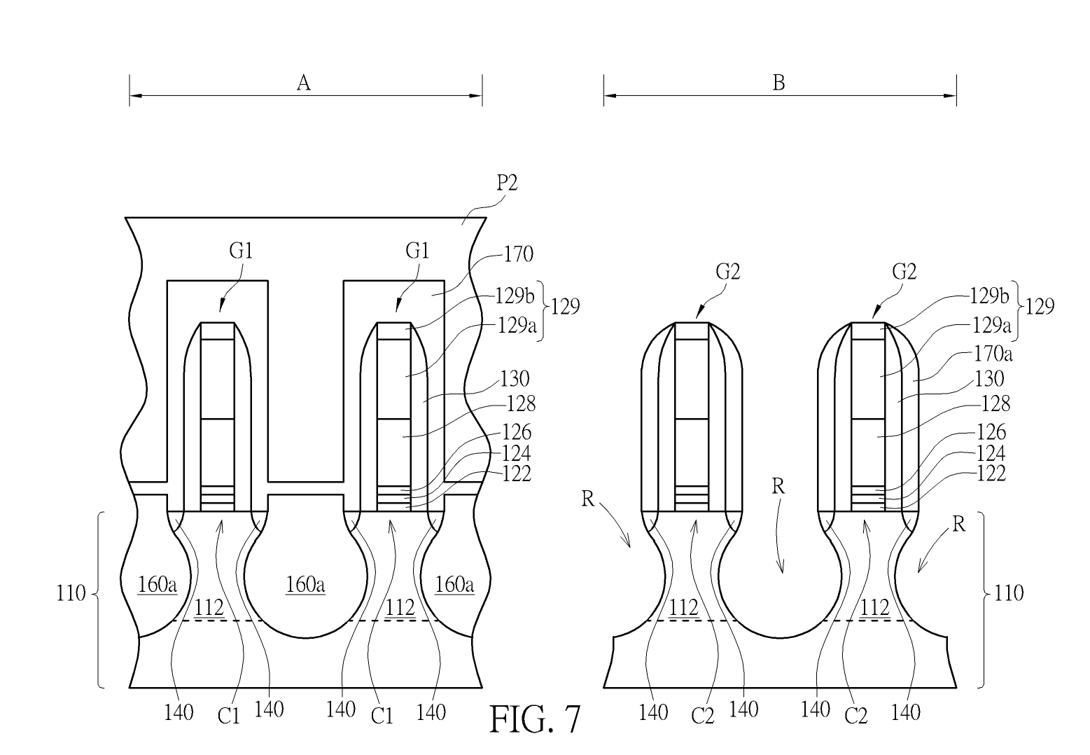

As shown in FIG. 7, the second stress layer 170 covering the second area B is etched to form a second spacer 170a with the capability of inducing stresses on the substrate 110 beside each of the second gates G2 while reserving the second stress layer 170 covering the first area A. More precisely, a material P2 covers the first area A while exposing the second area B, and then the second stress layer 170 covering the second area B is etched to form the second spacer 170a on the substrate 110 beside each of the second gates G2 while reserving the second stress layer 170 in the first area A.

After the second spacers 170a are formed, recesses R may be formed in the substrate 110 beside the second spacers 170a. In this embodiment, the recesses R extend to the substrate 110 below the fin-shaped structures 112. In another embodiment, the recesses R may just be formed in the fin-shaped structures 112, depending upon the electrical demands. In this embodiment, the second spacers 170a and the recesses R are formed during the same process for simplifying the processes. In another embodiment, the second spacer 170a and the recesses R may be formed through different processes, and the second spacers 170a and the recesses R may be formed through several processes respectively. Thereafter, the material P2 in the first area A is removed. In this embodiment, the material P2 is a light sensitive material such as a photoresist, but it is not limited thereto. After the material P2 is covered, a partial stress strengthening process such as an ultraviolet (UV) light illuminating process may be selectively performed in the second area B to enhance stresses in the gate channels C2 induced by the second stress layer 170 or the second spacers 170a.

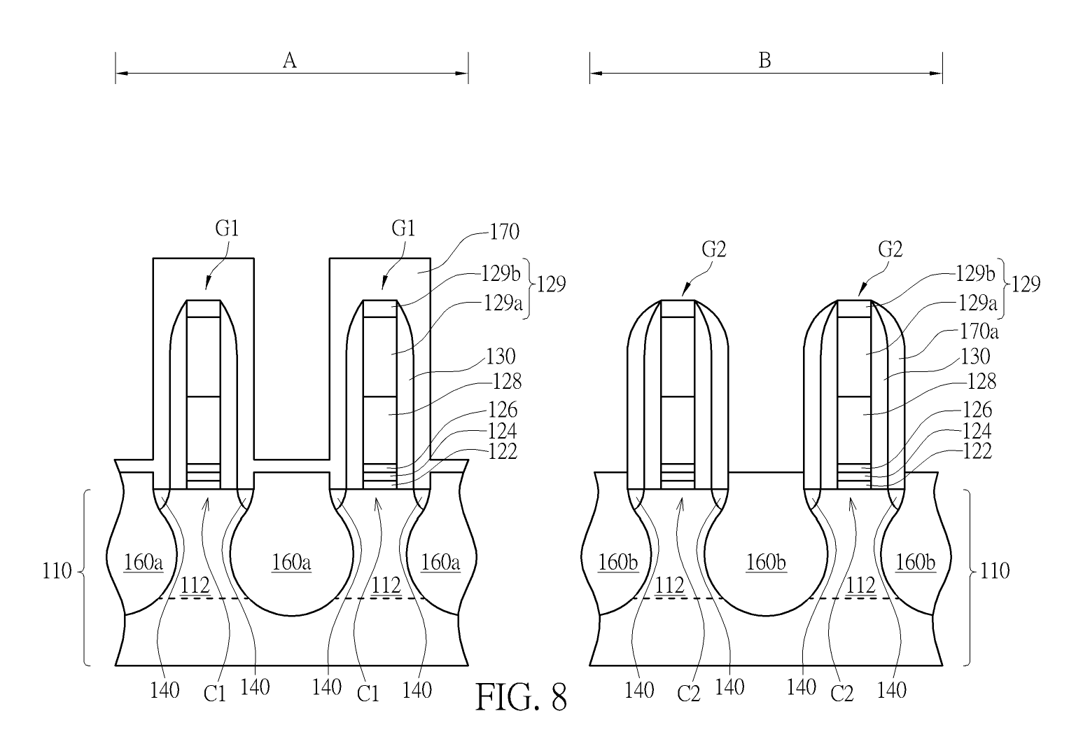

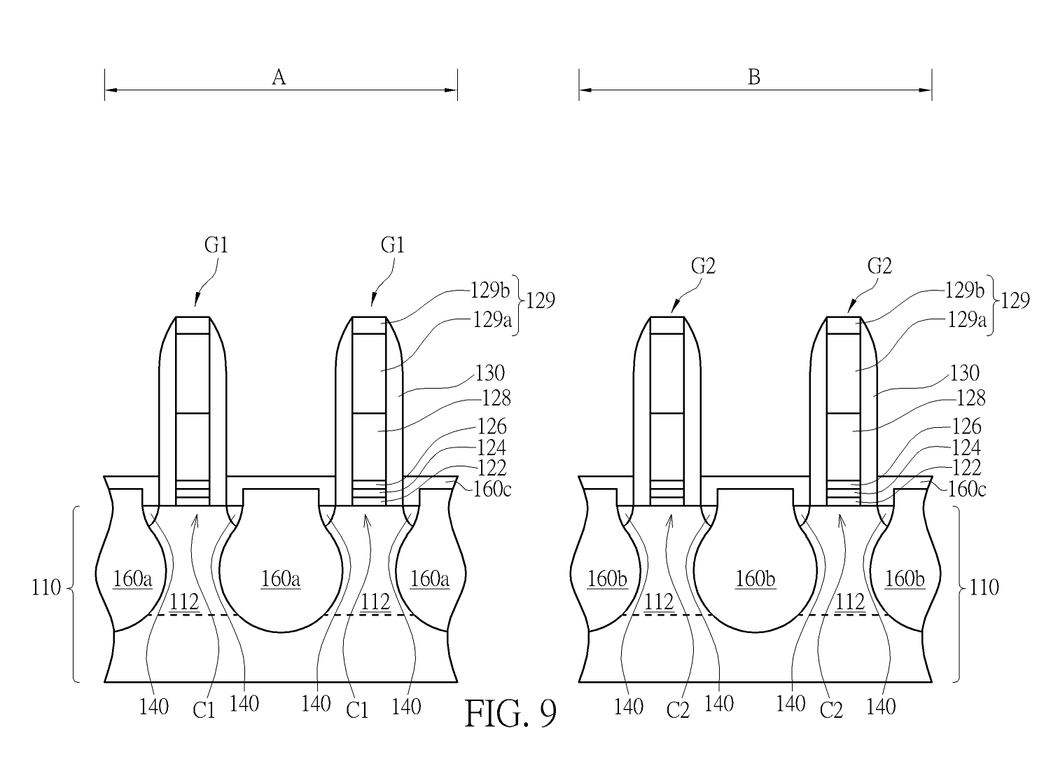

As shown in FIG. 8, a second epitaxial layer 160b is formed in each of the recesses R. In this embodiment, since the NMOS transistors are formed in the second area B, the second epitaxial layers 160b may preferably be silicon phosphorus or silicon carbon epitaxial layers, but it is not limited thereto. Then, the second stress layer 170 and the second spacers 170a may be removed at the same time as shown in FIG. 9. In this embodiment, the recesses R are formed and then the second epitaxial layers 160b are formed in the recesses R. In another embodiment, the second epitaxial layers 160b may be formed in the substrate 110 beside the second spacers 170a by doping the substrate 110 directly without forming the recesses R first. As shown in FIG. 9, a cap layer 160c may be selectively formed on each of the first epitaxial layers 160a and the second epitaxial layers 160b simultaneously. The cap layer 160c may be a silicon layer to prevent ingredients such as germanium or phosphorus in the first epitaxial layers 160a and the second epitaxial layers 160b from diffusing upwards, while the first epitaxial layers 160a and the second epitaxial layers 160b can be electrically connected to later formed structures above, but it is not limited thereto.

After the second epitaxial layers 160b or the cap layers 160c are formed, the steps of forming the lightly doped source/drains 140 may be selectively performed at this time instead.

Furthermore, after the first stress layer 150 or/and the second stress layer 170 are formed, a thermal or/alight illuminating process may be further performed, enabling stresses in the gate channels C1 or/and the gate channels C2 induced by the first stress layer 150 or/and the second stress layer 170 to be enhanced. For example, a thermal process may be performed right after the first stress layer 150 or/and the second stress layer 170 is formed; or, after the first epitaxial layers 160a or/and the second epitaxial layers 160b are formed. When the thermal process is performed before the first epitaxial layers 160a or/and the second epitaxial layers 160b are formed, the degradation of the first epitaxial layers 160a or/and the second epitaxial layers 160b caused by the processing temperature of the thermal process can be avoided. When the thermal process is performed after the first stress layer 150 and the second stress layer 170 are formed, the thermal process is only needed to be performed once on the first stress layer 150 and the second stress layer 170, the process can be simplified and the processing costs can be reduced. The two effects can be traded off in practical circumstances.

Moreover, when forming the first stress layer 150, the first spacers 150a serving as spacers for forming the first epitaxial layers 160a and then forming the first epitaxial layers 160a; forming the second stress layer 170, forming the second spacers 170a serving as spacers for forming the second epitaxial layers 160b and then forming the second epitaxial layers 160b, various silicon strain technologies can be integrated into CMOS transistors having PMOS transistors and NMOS transistors, and the processing steps can be simplified. In other words, compressive stresses in the gate channels C1 of the first area A for forming PMOS transistors can be induced by the first stress layer 150 and the first epitaxial layers 160a, and tensile stresses in the gate channels C2 of the second area B for forming NMOS transistors can be induced by the second stress layer 170 and the second epitaxial layers 160b.

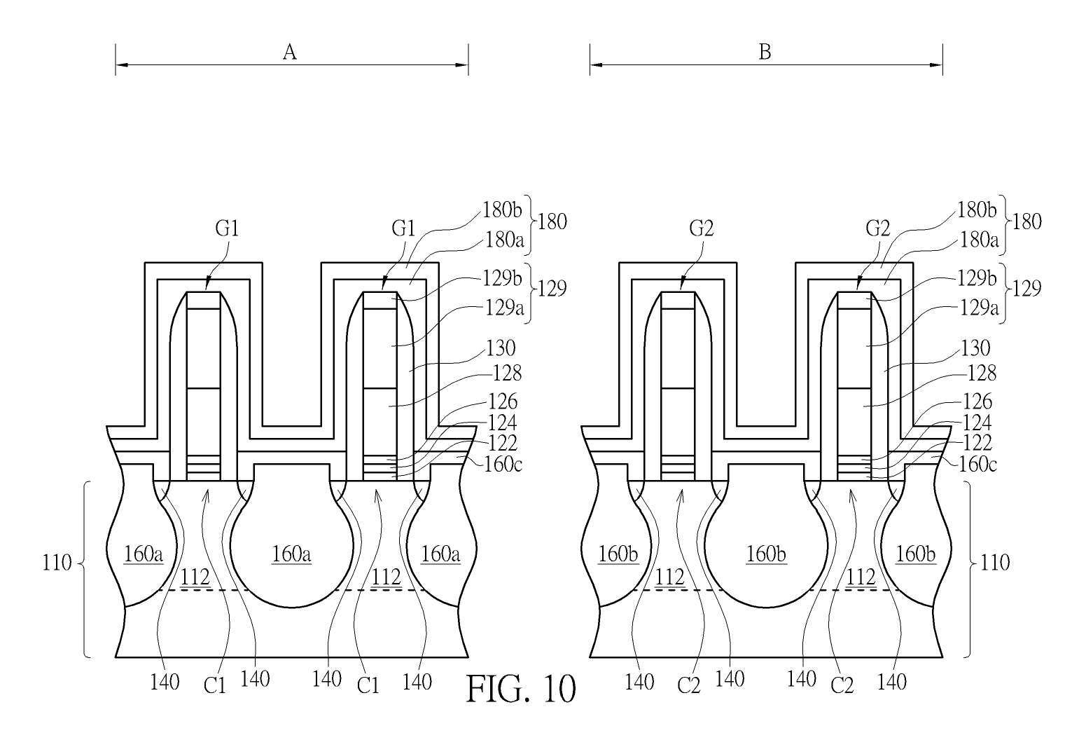

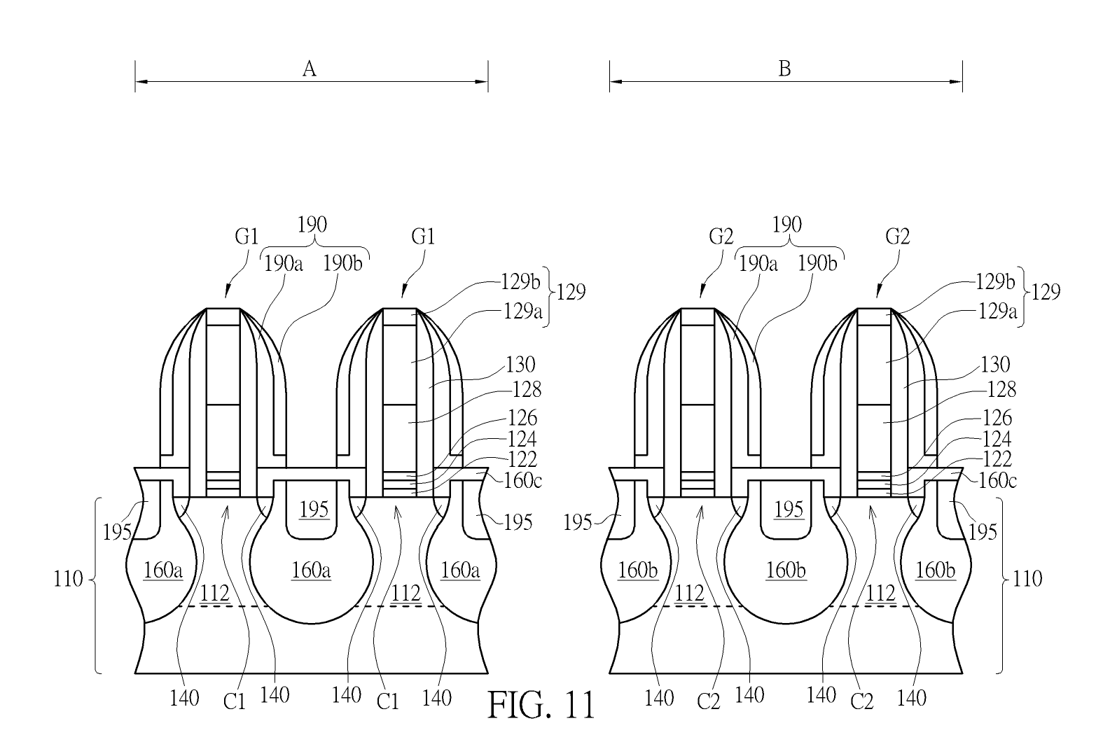

As shown in FIG. 10, a main spacer material 180 is formed to entirely cover the first gates G1 and the second gates G2. The main spacer material 180 may be a single layer or a multilayer composed of nitride or oxide etc. For example, the main spacer material 180 may include an oxide layer 180a and a nitride layer 180b, but it is not limited thereto. Then, the main spacer material 180 is etched to form main spacers 190 on the substrate 110 beside the first gates G1 and the second gates G2 as shown in FIG. 11. In one case, the oxide layer 180a and the nitride layer 180b may be etched simultaneously to form the main spacers 190 being dual spacers having L-shaped inner spacers 190a. In another case, only the nitride layer 180b is etched, so as to form single outer spacers 190b while reserving the oxide layer 180a covering the first epitaxial layers 160a and the second epitaxial layers 160b. Thereafter, an ion implantation process may be performed to form source/drains 195 in the substrate 110 beside the main spacers 190. Then, later semiconductor processes may be performed.

To summarize, the present invention provides a semiconductor process, which forms a first stress layer, a first spacer from the first stress layer, then a first epitaxial layer by the first spacer; thereafter, forms a second stress layer, a second spacer from the second stress layer, and then a second epitaxial layer by the second spacer. In this way, various crystal strain technologies can be integrated into semiconductor structures, and processes can be simplified. Moreover, compressive stresses can be induced in a gate channel for forming a PMOS transistor by the first stress layer and the first epitaxial layer, and tensile stresses can be induced in a gate channel for forming an NMOS transistor by the second stress layer and the second epitaxial layer through selecting the materials of the first stress layer, the first epitaxial layer, the second stress layer and the second epitaxial layer, thereby integrating various crystal strain technologies into a CMOS transistor.

Moreover, lightly doped source/drains can be formed before the first stress layer is formed, after the first epitaxial layer is formed or after the second epitaxial layer is formed. Furthermore, a thermal process or a light illuminating process for enhancing stresses induced by the first stress layer and the second stress layer may be performed after the first stress layer or/and the second stress layer is formed, or after the first epitaxial layer or/and the second epitaxial is formed.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor process, comprising:
forming a first gate and a second gate on a substrate;
forming a first stress layer to cover the first gate and the second gate;
etching the first stress layer covering the first gate to form a first spacer on the substrate beside the first gate, but reserving the first stress layer covering the second gate;
forming a first epitaxial layer in the substrate beside the first spacer, wherein the stresses induced by the first stress layer and the first epitaxial layer are the same type;
removing the first stress layer and the first spacer completely;
forming a second stress layer to cover the first gate and the second gate;
etching the second stress layer covering the second gate to form a second spacer on the substrate beside the second gate, but reserving the second stress layer covering the first gate;
forming a second epitaxial layer in the substrate beside the second spacer, wherein the stresses induced by the second stress layer and the second epitaxial layer are the same type; and
removing the second stress layer and the second spacer completely.

2. The semiconductor process according to claim 1, further comprising:
performing a partial stress strengthening process after the first stress layer is formed.

3. The semiconductor process according to claim 2, wherein the partial stress strengthening process comprises an ultraviolet (UV) light illuminating process.

4. The semiconductor process according to claim 2, further comprising:
forming two lightly doped source/drains in the substrate beside the spacers after the spacers are formed.

5. The semiconductor process according to claim 2, further comprising:
forming two lightly doped source/drains in the substrate beside the spacers after the first stress layer and the first spacer are removed completely.

6. The semiconductor process according to claim 2, further comprising:
forming two lightly doped source/drains in the substrate beside the spacers after the second stress layer and the second spacer are removed completely.

7. The semiconductor process according to claim 1, wherein the first gate is a gate of a PMOS transistor and the second gate is a gate of an NMOS transistor.

8. The semiconductor process according to claim 7, wherein the first epitaxial layer comprises a silicon germanium epitaxial layer.

9. The semiconductor process according to claim 7, wherein the second epitaxial layer comprises a silicon phosphorus epitaxial layer.

10. The semiconductor process according to claim 7, wherein the first stress layer comprises a compressive stress layer.

11. The semiconductor process according to claim 7, wherein the second stress layer comprises a tensile stress layer.

12. The semiconductor process according to claim 1, further comprising:
forming a material to cover the first stress layer covering the second gate to reserve the first stress layer covering the second gate while etching before the first stress layer covering the first gate is etched.

13. The semiconductor process according to claim 1, further comprising:
forming a material to cover the second stress layer covering the first gate to reserve the second stress layer covering the first gate while etching before the second stress layer covering the second gate is etched.

14. The semiconductor process according to claim 1, wherein the steps of forming the first epitaxial layer comprise:
forming a recess in the substrate beside the first spacer; and
forming the first epitaxial layer in the recess.

15. The semiconductor process according to claim 1, wherein the steps of forming the second epitaxial layer comprise:
forming a recess in the substrate beside the second spacer; and
forming the second epitaxial layer in the recess.

16. The semiconductor process according to claim 1, further comprising:
forming a cap layer on the first epitaxial layer and the second epitaxial layer respectively after the second stress layer and the second spacer are removed completely.

17. The semiconductor process according to claim 1, further comprising:
forming two main spacers on the substrate beside the first gate and the second gate after the second stress layer and the second spacer are removed completely.

18. The semiconductor process according to claim 17, wherein the steps of forming the main spacers comprise:
forming a main spacer material to cover the first gate and the second gate; and
etching the main spacer material to form the main spacers.

19. The semiconductor process according to claim 17, wherein the main spacers comprise dual spacers.

20. The semiconductor process according to claim 17, further comprising:
forming two source/drains in the substrate beside the main spacers after the main spacers are formed.
